(19) United States
(12) Patent Application Publication
(10) Pub. No.: US 2025/0274095 A1
(43) Pub. Date: Aug. 28, 2025

(54) MULTI-TERMINAL BULK ACOUSTIC WAVE RESONATOR UTILIZING OVERTONE MODES

(71) Applicant: SKYWORKS SOLUTIONS, INC., Irvine, CA (US)

(72) Inventor: Ahmed E. Hassanien, Savoy, IL (US)

(21) Appl. No.: 19/050,372

(22) Filed: Feb. 11, 2025

Related U.S. Application Data
(60) Provisional application No. 63/558,387, filed on Feb. 27, 2024.

(51) Int. Cl. H03H 9/02; H03H 9/17; H03H 9/56

(52) U.S. Cl. CPC H03H 9/02062; H03H 9/172; H03H 9/568

(57) ABSTRACT

A bulk acoustic wave resonator includes a material layer stack located in a central active region and comprising a lower piezoelectric material layer disposed on an upper surface of a bottom electrode, a middle electrode disposed on an upper surface of the lower piezoelectric material layer, an upper piezoelectric material layer disposed on an upper surface of the middle electrode, and a top electrode disposed on an upper surface of the upper piezoelectric material layer, the bulk acoustic wave resonator configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stack.

### CROSS-REFERENCE TO RELATED APPLICATIONS

This application claims priority under 35 U.S.C. § 119 (e) to U.S. Provisional Patent Application Ser. No. 63/558,387, titled “MULTI-TERMINAL BULK ACOUSTIC WAVE RESONATOR UTILIZING OVERTONE MODES,” filed Feb. 27, 2024, the entire content of which is incorporated herein by reference for all purposes.

### BACKGROUND

### Technical Field

Embodiments of this disclosure relate to bulk acoustic wave resonators and to acoustic wave filters including same in which the bulk acoustic wave resonators utilize an overtone of vibration of their piezoelectric material films to generate the main acoustic waves used by the resonators.

### Description of Related Technology

Acoustic wave filters can filter radio frequency signals. An acoustic wave filter can include a plurality of resonators arranged to filter a radio frequency signal. The resonators can be arranged as a ladder circuit. Example acoustic wave filters include surface acoustic wave (SAW) filters, bulk acoustic wave (BAW) filters, and Lamb wave resonator filters. A film bulk acoustic resonator filter is an example of a BAW filter. A solidly mounted resonator (SMR) filter is another example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a bulk acoustic wave resonator including a material layer stack located in a central active region of the bulk acoustic wave resonator. The material layer stack comprises a bottom electrode, a lower piezoelectric material layer disposed on an upper surface of the bottom electrode, a middle electrode having a lower surface disposed on an upper surface of the lower piezoelectric material layer, an upper piezoelectric material layer having a lower surface disposed on an upper surface of the middle electrode, and a top electrode having a lower surface disposed on an upper surface of the upper piezoelectric material layer. The bulk acoustic wave resonator is configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stack.

In some embodiments, the lower piezoelectric material layer has a same thickness as the upper piezoelectric material layer.

In some embodiments, the lower piezoelectric material layer has a same chemical composition as the upper piezoelectric material layer.

In some embodiments, the bulk acoustic wave resonator is configured to generate an acoustic wave in the lower piezoelectric material layer that is 180° out of phase with an acoustic wave generated in the upper piezoelectric material layer responsive to application of the electrical signal.

In some embodiments, the bulk acoustic wave resonator is further configured to generate a main acoustic wave at a fundamental vibrational mode responsive to application of an electrical signal to the bottom electrode that is 180° out of phase with a signal applied to the top electrode.

In some embodiments, the bottom electrode has a same thickness as the top electrode.

In some embodiments, the middle electrode has a different thickness than either of the bottom electrode or the top electrode.

In some embodiments, the middle electrode is thicker than both of the bottom electrode and the top electrode.

In some embodiments, the bulk acoustic wave resonator is configured as a film bulk acoustic wave resonator.

In some embodiments, the bulk acoustic wave resonator is configured as a solidly mounted resonator.

In some embodiments, the bulk acoustic wave resonator is included in a radio frequency filter including.

In some embodiments, the radio frequency filter is configured as a ladder filter.

In some embodiments, the radio frequency filter is included in a radio frequency module.

In some embodiments, the radio frequency modules is included in a radio frequency device.

In accordance with another aspect, there is provided a radio frequency ladder filter including a plurality of bulk acoustic wave resonators each having a material layer stack located in a central active region. The material layer stack of each of the bulk acoustic wave resonators comprises a bottom electrode, a lower piezoelectric material layer disposed on an upper surface of the bottom electrode, a middle electrode having a lower surface disposed on an upper surface of the lower piezoelectric material layer, an upper piezoelectric material layer having a lower surface disposed on an upper surface of the middle electrode, and a top electrode having a lower surface disposed on an upper surface of the upper piezoelectric material layer, a first subset of the plurality of bulk acoustic wave resonators being series arm resonators, a second subset of the plurality of bulk acoustic wave resonators being shunt resonators and having a lower resonant frequency than the series arm resonators.

In some embodiments, the series arm resonators are configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stacks of the series arm resonators.

In some embodiments, the shunt resonators are configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stacks of the shunt resonators.

In some embodiments, the lower piezoelectric material layers and the upper piezoelectric material layers of the shunt resonators have same thicknesses as the lower piezoelectric material layers and the upper piezoelectric material layers of the series arm resonators.

In some embodiments, one or more of the bottom electrodes, middle electrodes, or top electrodes of the shunt resonators have greater thicknesses than corresponding ones of the bottom electrodes, middle electrodes, or top electrodes of the series arm resonators.

In some embodiments, the shunt resonators are configured to generate a main acoustic wave at a fundamental vibrational mode responsive to application of electrical signals to the bottom electrodes of the shunt resonators that are 180° out of phase with signals applied to the top electrodes of the shunt resonators.

In some embodiments, the shunt resonators and series arm resonators are disposed on a same die.

### BRIEF DESCRIPTION OF THE DRAWINGS

Embodiments of this disclosure will now be described, by way of non-limiting example, with reference to the accompanying drawings.

FIG. 1 is a cross-sectional view of an example of film bulk acoustic wave resonator;

FIG. 2 is a cross-sectional view of an example of a solidly mounted resonator;

FIG. 3 illustrates examples of stacks of material layers including and disposed above and below piezoelectric material layers of BAW resonators that may be utilized, for example, as series or shunt resonators in a ladder filter;

FIG. 4 illustrates a material layer stack in a central active region of a BAW resonator in which a second overtone vibrational mode is excited;

FIG. 5 illustrates how a BAW resonator having a material layer stack as illustrated in FIG. 4 may be operated to generate either a fundamental vibrational mode or a second overtone vibrational mode depending on how different signals are applied to the different electrodes;

FIG. 6 illustrates how BAW resonators having a material layer stack as illustrated in FIG. 4 may be tailored to generate second overtone vibrational modes at different frequencies depending on the thickness of the electrodes in the material layer stack;

FIG. 7 illustrates a simplified schematic diagram of a ladder filter that may be formed from resonators as disclosed herein;

FIG. 8 illustrates an embodiment of an electronics module;

FIG. 9 illustrates an example of a front-end module which may be used in an electronic device; and

FIG. 10 illustrates an example of an electronic device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators are a form of bulk acoustic wave resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A film bulk acoustic wave resonator exhibits a frequency response to applied signals with a resonance peak determined in part by a thickness of the film of piezoelectric material. Ideally, the only acoustic wave that would be generated in a film bulk acoustic wave resonator is a main acoustic wave that would travel through the film of piezoelectric material in a direction perpendicular to layers of conducting material forming the top and bottom electrodes. The piezoelectric material of a film bulk acoustic wave resonator, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the film bulk acoustic wave resonator from what is expected or from what is intended and are generally considered undesirable.

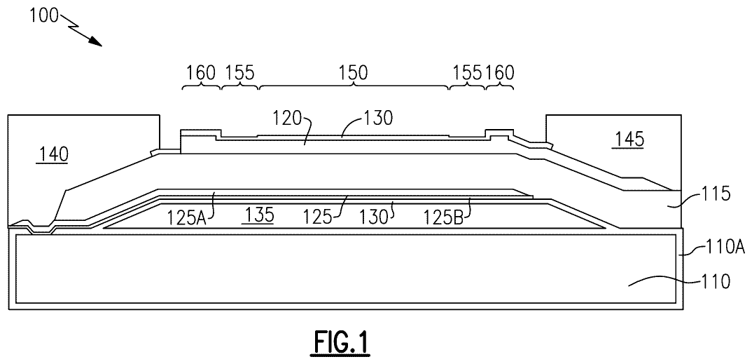

FIG. 1 is cross-sectional view of an example of a film bulk acoustic wave resonator, indicated generally at 100. The film bulk acoustic wave resonator 100 is disposed on a substrate 110, for example, a silicon substrate that may include a dielectric surface layer 110A of, for example, silicon dioxide. The film bulk acoustic wave resonator 100 includes a layer or film of piezoelectric material 115, for example, aluminum nitride (AlN) or scandium-doped aluminum nitride (AlₓSc₁₋ₓN, referred to herein without subscripts as AlScN). A top electrode 120 (often abbreviated MTE for Metal Top Electrode) is disposed on top of a portion of the layer or film of piezoelectric material 115 and a bottom electrode 125 (often abbreviated MBE for Metal Bottom Electrode) is disposed on the bottom of a portion of the layer or film of piezoelectric material 115. The top electrode 120 may be formed of, for example, ruthenium (Ru). The bottom electrode 125 may include a layer 125A of Ru disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the surface layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The film bulk acoustic wave resonator 100 may include a central region 150 (also referred to as a central active region) including a main active domain in the layer or film of piezoelectric material 115 in which a main acoustic wave is excited during operation. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm.

The recessed frame region(s) 155 and the raised frame region(s) 160 may contribute to dissipation or scattering of transverse acoustic waves generated in the film bulk acoustic wave resonator 100 during operation and/or may reflect transverse waves propagating outside of the recessed frame region(s) 155 and the raised frame region(s) 160 and prevent these transverse acoustic waves from entering the central region and inducing spurious signals in the main active domain region of the film bulk acoustic wave resonator. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

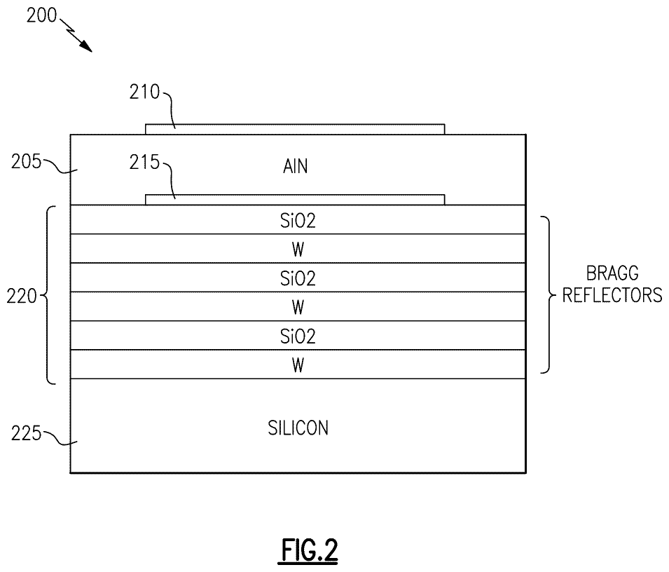

Another form of BAW resonator is a solidly mounted resonator (SMR). An example of an SMR is illustrated generally at 200 in FIG. 2. As illustrated, the SMR 300 includes a piezoelectric material layer 205, an upper electrode 210 (MTE) on the piezoelectric material layer 205, and a lower electrode 215 (MBE) on a lower surface of the piezoelectric material layer 205. The piezoelectric material layer 205 can be an AlN or AlScN layer. In other instances, the piezoelectric material layer 205 can be formed of any other suitable piezoelectric material. The lower electrode 215 can be grounded in certain instances. In some other instances, the lower electrode 215 can be floating. Bragg reflectors 220 are disposed between the lower electrode 215 and a semiconductor substrate 225. The semiconductor substrate 225 can be a silicon substrate. Any suitable Bragg reflectors can be implemented. For example, the Bragg reflectors can be SiO₂/W.

It should be appreciated that the BAW resonators and piezoelectric material layers illustrated in the figures are illustrated in a highly simplified form. The relative dimensions of the different features are not shown to scale. Further, typical BAW resonators may include additional features or layers not illustrated.

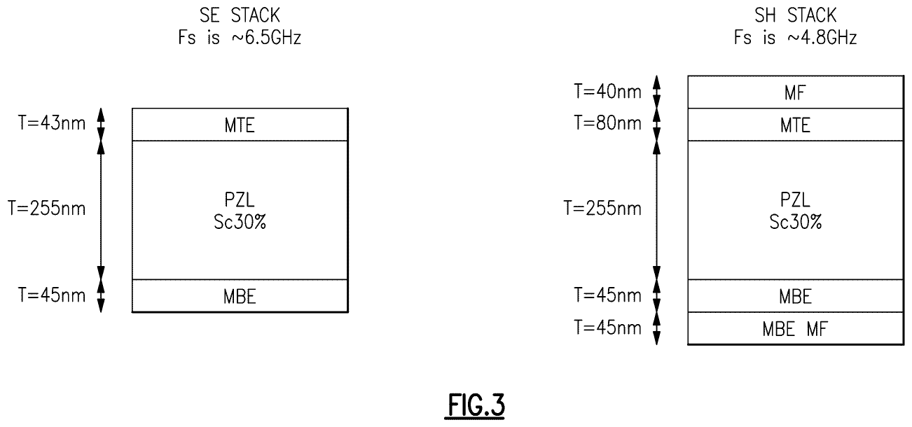

As noted above, the operating frequency of a BAW resonator is at least in part dependent on the thickness of the piezoelectric material film within the BAW resonator; generally, the thinner the piezoelectric material film the higher the operating frequency. The market is continuing to demand wireless devices operating at higher and higher frequencies. Piezoelectric material layers in BAW resonators, however, can only be made so thin before manufacturing repeatability, operational reliability, ruggedness, and quality factor begin to suffer. In the past most BAW resonators utilized an acoustic wave that was generated at the fundamental tone or first harmonic frequency of vibration of their piezoelectric material layers. As illustrated in FIG. 3 to achieve an admittance response for a series arm resonator in a ladder filter used, for example, for the WiFi 7 band, with a first harmonic or fundamental mode resonance frequency of about 6.5 GHZ, the piezoelectric film layer has a thickness of 255 nm and the top and bottom electrode thicknesses are 43 nm and 45 nm, respectively (the “SE Stack” in FIG. 3). A corresponding shunt resonator may have the same piezoelectric material layer thickness of 255 nm, but thicker upper and lower electrode thicknesses—80 nm and 40 nm, respectively—as well as upper and lower mass loading films MF and MBF to achieve an admittance response with a first harmonic or fundamental mode resonance frequency of about 4.8 GHz. These piezoelectric material layer thicknesses are very thin and may result in the resonators being less rugged than desirable. Additionally, the electrode layers are so thin that electrical resistance may be higher than desired.

It has been discovered that it is possible to increase the total thickness of the piezoelectric material film and of the electrodes of a BAW resonator (either a film bulk acoustic wave resonator or solidly mounted resonator) while still operating at a desired high frequency by designing the BAW resonator to utilize the second overtone or second harmonic of the piezoelectric material film stack as the main acoustic wave of the resonator. The second overtone or second harmonic is typically about twice the frequency of the fundamental mode or first harmonic, subject to some reduction in frequency due to the mass of the electrodes and other material layers deposited on or below the piezoelectric material layer of the resonator. Utilizing the second harmonic rather than the first harmonic of BAW resonators in a RF filter may provide for the filter to operate at higher frequencies without having to reduce the thickness of the piezoelectric material films of the resonators to thicknesses that might cause manufacturing repeatability or operational reliability issues.

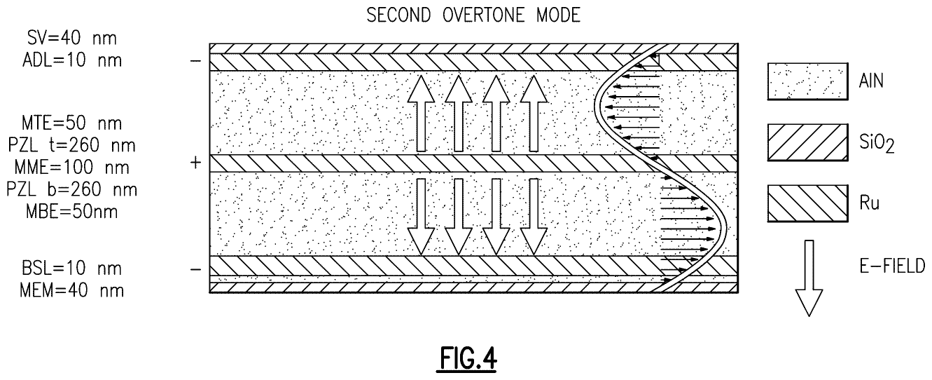

FIG. 4 illustrates one example of a material stack for the central active region of a BAW resonator (either a film bulk acoustic wave resonator or solidly mounted resonator) that may exhibit a second harmonic resonance frequency of about 7.1 GHZ, even higher than that of the SE stack of FIG. 3, but with a significantly greater thickness. In the material layer stack of FIG. 4 the piezoelectric material layer is broken into an upper piezoelectric material layer (PZL_t) and a lower piezoelectric material layer (PZL_b) separated by a middle electrode (MME). The upper and lower piezoelectric material layers may have the same thicknesses and may be formed of the same material, for example, AlN or AlScN. The upper piezoelectric material layer and lower piezoelectric material layer may have the same thickness, for example, 260 nm in the example of FIG. 4, for a combined piezoelectric material layer thickness of 520 nm, that is more than twice the piezoelectric material thickness of the resonator material stacks illustrated in FIG. 3. Top and bottom electrodes, MTE and MBE, are disposed on top of the upper piezoelectric material layer and on the bottom of the lower piezoelectric material layer, respectively. The middle electrode may have a thickness of, for example, 100 nm. The top and bottom electrodes may have thicknesses of, for example, 50 nm each for a combined outer electrode thickness of 100 nm. These electrode thicknesses are significantly greater than those in the examples of FIG. 3, which may lead to reduced electrical resistance and increased ruggedness. Each of the top, bottom, and middle electrodes may be formed of the same material, for example, ruthenium. Additional layers may also be present in some embodiments, such as an adhesion layer (ADL) with a thickness of, for example, 10 nm, an upper protective/trimming film layer (SV) with a thickness of, for example, 40 nm, a seed layer (BSL) with a thickness of, for example, 10 nm, and a lower protective film layer (MEM) with a thickness of, for example, 40 nm.

Signals that are 180° out of phase are applied to the middle electrode as opposed to the top and bottom electrodes such that at any one instant in time opposite charges are applied to the middle electrode as opposed to the top and bottom electrodes. The charges applied to the electrodes are alternated at a frequency that causes the material layer stack as a whole to vibrate at its second overtone without generation of a fundamental vibrational mode. The electric field in the upper piezoelectric material layer is in the opposite direction of the electric field in the lower piezoelectric material layer to cause the acoustic waves generated in the upper and lower piezoelectric material layers to be 180° out of phase with one another. This may be useful in suppressing higher order spurious modes because spurious vibrational modes generated in the upper piezoelectric material layer may be 180° out of phase with spurious vibrational modes generated in the lower piezoelectric material layer and may thus cancel out.

A BAW with the material layer stack with the example dimensions and materials as illustrated in FIG. 4 in its central active region may exhibit a resonant frequency at its second overtone of about 7.1 GHz. If one wished to include additional resonators on the same die as resonators having the material layer stack shown in FIG. 4, but operating at a lower frequency, one may form the lower frequency resonators with the same material layer stack as shown in FIG. 4 but apply signals with opposite alternating charges to the top and bottom electrodes while leaving the middle electrode electrically floating. This may result in excitation of the fundamental mode in the lower frequency resonators, for example, with a resonant frequency of about 4.3 GHZ as shown in FIG. 5. The lower frequency resonators may be utilized as shunt resonators in a ladder filter while the resonators operating at the higher frequency second overtone may be utilized as series resonators in the ladder filter.

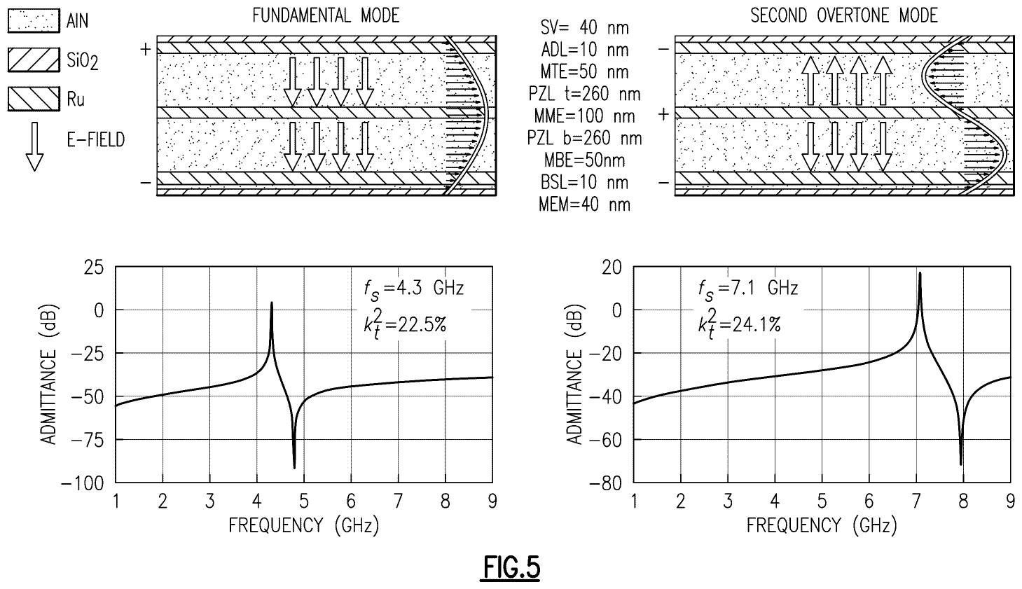

If one wished to form lower frequency BAW resonators and higher frequency BAW resonators for use in forming a ladder filter, with both the lower frequency BAW resonators and higher frequency BAW resonators utilizing their second overtones, one may utilize thicker electrodes in the lower frequency BAW resonators than in the higher frequency BAW resonators. For example, as illustrated in FIG. 6, BAW resonators with material stacks as illustrated in FIG. 4, exhibiting a second overtone resonance at 7.1 GHz, could be utilized as series resonators in a ladder filter. The shunt resonators may be formed by increasing the thickness of the middle electrode from 100 nm to 200 nm and increasing the thickness of each of the top and bottom electrodes from 50 nm to 100 nm, which may result in the lower frequency shunt resonators exhibiting a second overtone resonance at about 4.8 GHz. The piezoelectric material layers may have the same thicknesses and/or compositions in both the series arm resonators and shunt resonators. The series and shunt resonators having the material layer stacks as illustrated in FIG. 6 may be formed on different wafers and electrically connected during packaging, or may be formed on the same wafer using different process steps to form the electrodes with the different thicknesses.

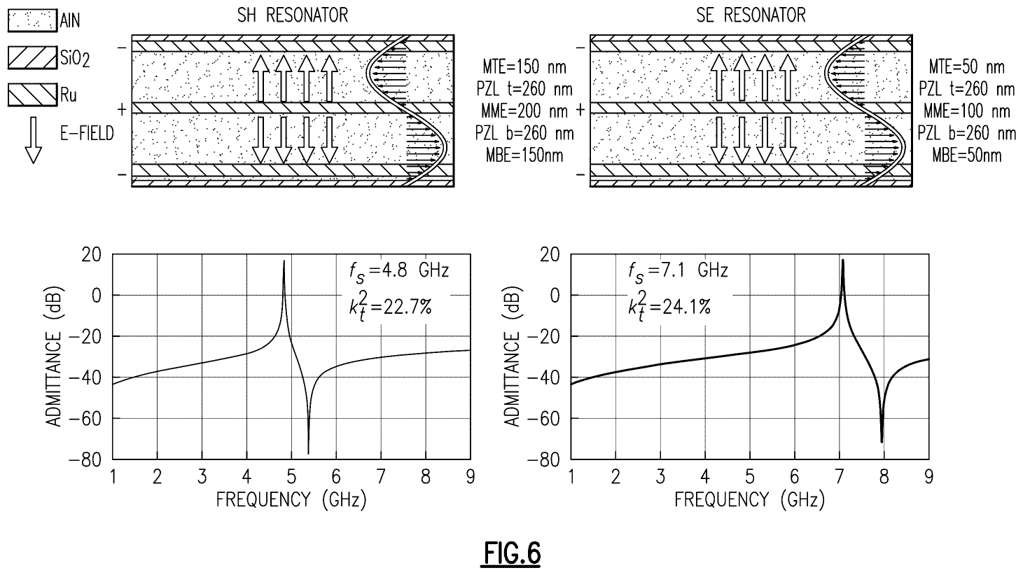

The acoustic wave devices discussed herein can be implemented in a variety of filters and packaged modules. Some example packaged modules will now be discussed in which any suitable principles and advantages of the packaged acoustic wave devices discussed herein can be implemented. FIGS. 7, 8, 9, and 10 are schematic block diagrams of an illustrative filter and packaged modules and devices according to certain embodiments.

As discussed above, embodiments of the disclosed BAW resonators can be configured as or used in filters, for example. In turn, a BAW filter using one or more BAW elements may be incorporated into and packaged as a module that may ultimately be used in an electronic device, such as a wireless communications device, for example.

In some embodiments, multiple BAW resonators as disclosed herein may be combined into a filter, for example, an RF ladder filter schematically illustrated in FIG. 7 and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration. Other filter structures and other circuit structures known in the art that may include BAW devices or resonators, for example, duplexers, baluns, etc., may also be formed including examples of BAW resonators as disclosed herein.

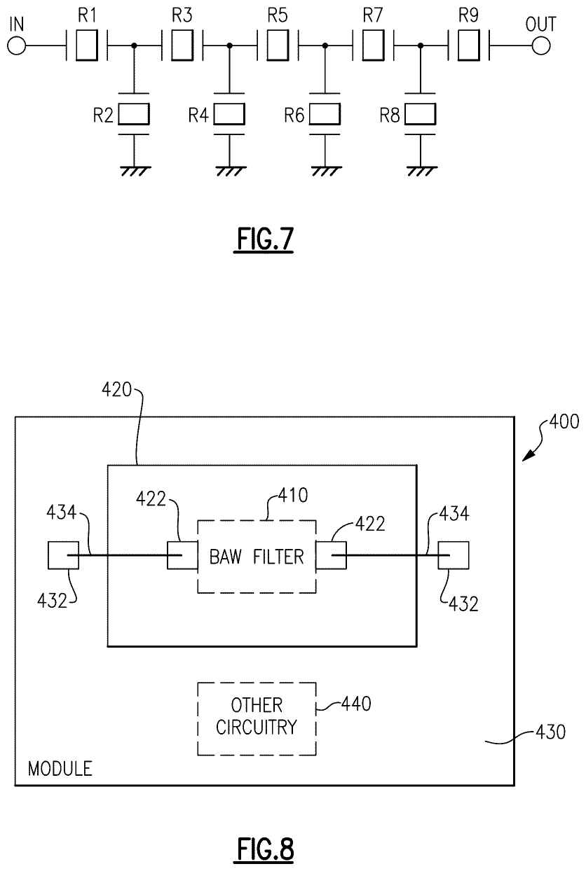

FIG. 8 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

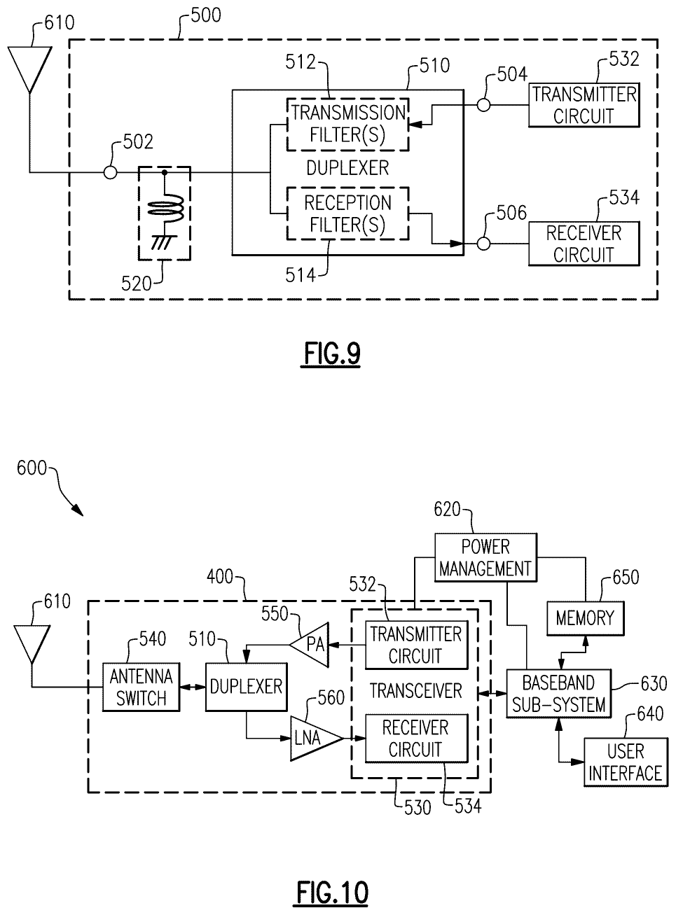

Referring to FIG. 9, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 9, however in other embodiments these components may be integrated into a common transceiver circuit or module. As will be appreciated by those skilled in the art, the front-end module 500 may include other components that are not illustrated in FIG. 9 including, but not limited to, switches, electromagnetic couplers, amplifiers, processors, and the like.

FIG. 10 is a block diagram of one example of a wireless device 600 including the antenna duplexer 510 shown in FIG. 9. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 9. The front-end module 500 includes the duplexer 510, as discussed above. In the example shown in FIG. 10 the front-end module 500 further includes an antenna switch 540, which can be configured to switch between different frequency bands or modes, such as transmit and receive modes, for example. In the example illustrated in FIG. 10, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 9.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 10, the front-end module 500 may further include a low noise amplifier module 560, which amplifies received signals from the antenna 610 and provides the amplified signals to the receiver circuit 534 of the transceiver 530.

The wireless device 600 of FIG. 10 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A bulk acoustic wave resonator including a material layer stack located in a central active region of the bulk acoustic wave resonator, the material layer stack comprising:
a bottom electrode;
a lower piezoelectric material layer disposed on an upper surface of the bottom electrode;
a middle electrode having a lower surface disposed on an upper surface of the lower piezoelectric material layer;
an upper piezoelectric material layer having a lower surface disposed on an upper surface of the middle electrode; and
a top electrode having a lower surface disposed on an upper surface of the upper piezoelectric material layer,
the bulk acoustic wave resonator configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stack.

2. The bulk acoustic wave resonator of claim 1 wherein the lower piezoelectric material layer has a same thickness as the upper piezoelectric material layer.

3. The bulk acoustic wave resonator of claim 1 wherein the lower piezoelectric material layer has a same chemical composition as the upper piezoelectric material layer.

4. The bulk acoustic wave resonator of claim 1 configured to generate an acoustic wave in the lower piezoelectric material layer that is 180° out of phase with an acoustic wave generated in the upper piezoelectric material layer responsive to application of the electrical signal.

5. The bulk acoustic wave resonator of claim 1 wherein the bulk acoustic wave resonator is further configured to generate a main acoustic wave at a fundamental vibrational mode responsive to application of an electrical signal to the bottom electrode that is 180° out of phase with a signal applied to the top electrode.

6. The bulk acoustic wave resonator of claim 1 wherein the bottom electrode has a same thickness as the top electrode.

7. The bulk acoustic wave resonator of claim 1 wherein the middle electrode has a different thickness than either of the bottom electrode or the top electrode.

8. The bulk acoustic wave resonator of claim 7 wherein the middle electrode is thicker than both of the bottom electrode and the top electrode.

9. The bulk acoustic wave resonator of claim 1 configured as a film bulk acoustic wave resonator.

10. The bulk acoustic wave resonator of claim 1 configured as a solidly mounted resonator.

11. A radio frequency filter including the bulk acoustic wave resonator of claim 1.

12. The radio frequency filter of claim 11 configured as a ladder filter.

13. A radio frequency module including the radio frequency filter of claim 12.

14. A radio frequency device including the radio frequency module of claim 13.

15. A radio frequency ladder filter including a plurality of bulk acoustic wave resonators each having a material layer stack located in a central active region, the material layer stack of each of the bulk acoustic wave resonators comprising:
a bottom electrode;
a lower piezoelectric material layer disposed on an upper surface of the bottom electrode;
a middle electrode having a lower surface disposed on an upper surface of the lower piezoelectric material layer;
an upper piezoelectric material layer having a lower surface disposed on an upper surface of the middle electrode; and
a top electrode having a lower surface disposed on an upper surface of the upper piezoelectric material layer,
a first subset of the plurality of bulk acoustic wave resonators being series arm resonators, a second subset of the plurality of bulk acoustic wave resonators being shunt resonators and having a lower resonant frequency than the series arm resonators.

16. The radio frequency ladder filter of claim 15 wherein the series arm resonators are configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stacks of the series arm resonators.

17. The radio frequency ladder filter of claim 16 wherein the shunt resonators are configured to generate a main acoustic wave at a second overtone vibrational mode responsive to application of an electrical signal to the bottom electrode and top electrode that is 180° out of phase with an electrical signal applied to the middle electrode, the second overtone vibrational mode being generated without generating an acoustic wave at a fundamental vibrational mode of the material layer stacks of the shunt resonators.

18. The radio frequency ladder filter of claim 17 wherein the lower piezoelectric material layers and the upper piezoelectric material layers of the shunt resonators have same thicknesses as the lower piezoelectric material layers and the upper piezoelectric material layers of the series arm resonators.

19. The radio frequency ladder filter of claim 18 wherein one or more of the bottom electrodes, middle electrodes, or top electrodes of the shunt resonators have greater thicknesses than corresponding ones of the bottom electrodes, middle electrodes, or top electrodes of the series arm resonators.

20. The radio frequency ladder filter of claim 16 wherein the shunt resonators are configured to generate a main acoustic wave at a fundamental vibrational mode responsive to application of electrical signals to the bottom electrodes of the shunt resonators that are 180° out of phase with signals applied to the top electrodes of the shunt resonators.
